(19) United States
(12) Patent Application Publication
(10) Pub. No.: US 2005/0218903 A1
(43) Pub. Date: Oct. 6, 2005

(54) Voltage waveform generation circuit

(75) Inventors: Vijay Kumar Reddy, Plano, TX (US); Prasun Raha, Richardson, TX (US)

Correspondence Address: TEXAS INSTRUMENTS INCORPORATED, P O BOX 655474, M/S 3999, DALLAS, TX, 75265, US

(73) Assignee: Taxas Instruments Incorported, Dallas, TX (US)

(21) Appl. No.: 10/814,453

(22) Filed: Mar. 31, 2004

(51) Int. Cl. G01R 31/08

(52) U.S. Cl. 324/520

(57) ABSTRACT

A method and apparatus permit voltage waveforms to be generated based, in part, on a request containing a plurality of waveform parameters. The voltage waveforms preferably represents voltage overshoot or undershoots.

### BACKGROUND

1. Technical Field

The present subject matter relates generally to generating voltage waveforms for testing electrical components. More specifically, the present subject matter relates to generating voltage waveforms for the purpose of injecting voltage overshoots and undershoots into electrical components.

2. Background Information

Integrated circuits (ICs) contain an ever-increasing number of electronic components. Very large scale integration (VLSI) circuits, for example, may contain millions of electrical components, most of which are transistors, on a single chip. In addition to the increasing number of electrical components, the operating frequency of such components and the minimum geometries of the technologies have also increased, introducing a variety of phenomena, such as negative bias temperature instability (NBTI) and channel hot carriers (CHC), that degrade component performance. Typically, component degradation models transform an alternating current (AC) waveform into discrete direct current (DC) parts. In these models, an effective DC signal is calculated and applied to the component for a predetermined duration depending upon the type of electrical component under test. Unfortunately, such degradation models may be unreliable and lead to conservative design techniques, such as guardbanding of the electrical component.

### BRIEF SUMMARY

In accordance with at least some embodiments of the invention, a method and apparatus are disclosed that permit voltage waveforms to be generated based, in part, on a request containing a plurality of waveform parameters. A preferred embodiment comprises creating a request the comprises a plurality of waveform parameters to generate a voltage waveform, processing the request to determine a plurality of inputs based, in part, on the plurality of parameters, applying the plurality of inputs to a waveform generation circuit, and generating a voltage waveform in accordance with at least one of the parameters. The voltage waveform preferably represents a voltage overshoot or undershoot.

Notation and Nomenclature

Certain terms are used throughout the following description and claims to refer to particular system components. As one skilled in the art will appreciate, various companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to.” Also, the term “couple” or “couples” is intended to mean either an indirect or direct connection. Thus, if a first device couples to a second device, that connection may be through a direct connection, or through an indirect connection via other devices and connections.

### BRIEF DESCRIPTION OF THE DRAWINGS

For a more detailed description of the preferred embodiments of the present invention, reference will now be made to the accompanying drawings, wherein:

FIG. 1 illustrates an exemplary waveform possessing a voltage overshoot;

FIG. 2 illustrates an exemplary waveform possessing a voltage undershoot;

FIG. 3 illustrates an exemplary test methodology in accordance with embodiments of the invention;

FIG. 4 illustrates a block diagram of a waveform generation system in accordance with embodiments of the invention;

FIG. 5 illustrates a preferred method of generating waveforms in accordance with embodiments of the invention;

FIG. 6 illustrates a block diagram of a waveform generation circuit for generating voltage overshoots in accordance with embodiments of the inventions;

FIG. 7 illustrates an exemplary waveform generated by the waveform generation circuit of FIG. 6;

FIG. 8 illustrates an exemplary circuit schematic of the waveform generation circuit of FIG. 5 in accordance with embodiments of the inventions;

FIG. 9 illustrates a block diagram of a waveform generation circuit for generating voltage undershoots in accordance with embodiments of the inventions;

FIG. 10 illustrates an exemplary waveform generated by the waveform generation circuit of FIG. 9; and

FIG. 11 illustrates an exemplary circuit schematic of the waveform generation circuit of FIG. 9 in accordance with embodiments of the inventions.

### DETAILED DESCRIPTION OF THE PREFERRED EMBODIMENTS

The following discussion is directed to various embodiments of the invention. Although one or more of these embodiments may be preferred, the embodiments disclosed should not be interpreted, or otherwise used, as limiting the scope of the disclosure, including the claims, unless otherwise specified. In addition, one skilled in the art will understand that the following description has broad application, and the discussion of any embodiment is meant only to be exemplary, of that embodiment, and not intended to intimate that the scope of the disclosure, including the claims, is limited to that embodiment.

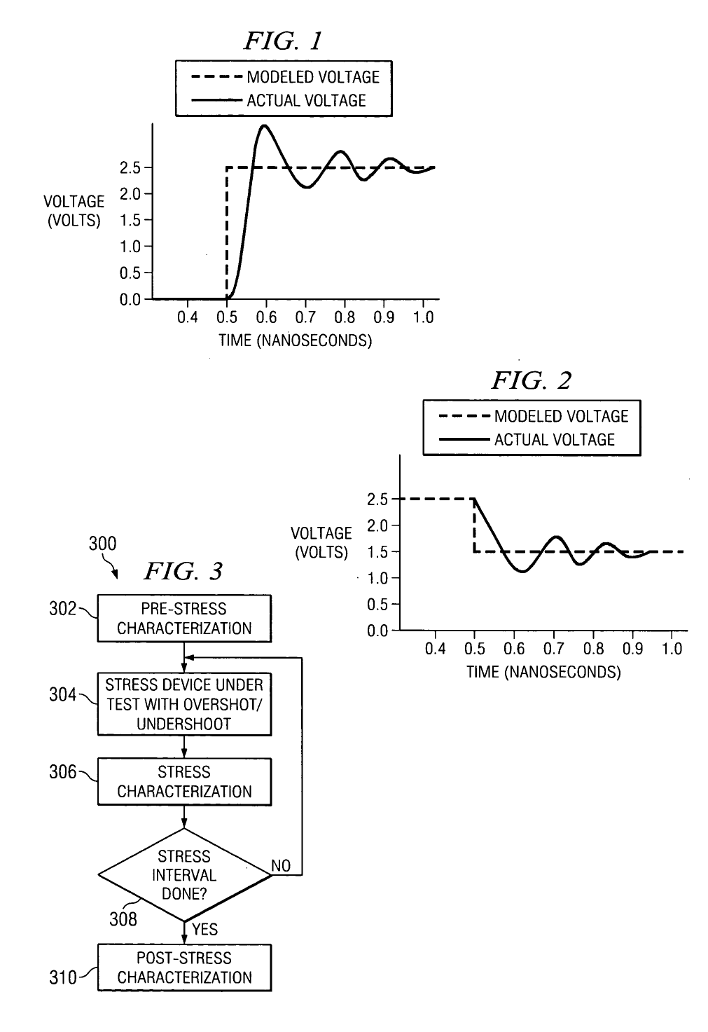

Referring now to FIG. 1, an exemplary waveform that exhibits a voltage overshoot is shown. The modeled voltage waveform is a square wave that steps from 0 volts to 2.5 volts at 0.5 nanoseconds (10⁻⁹ seconds). The actual voltage generated in response to the modeled voltage “overshoots” the modeled voltage at approximately 0.6 nanoseconds before settling to the desired voltage at approximately 1.0 nanosecond. Overshoots may occur during a transition from a lower voltage value to a higher voltage value.

FIG. 2 illustrates an exemplary waveform that exhibits a voltage undershoot. The modeled voltage waveform is a square wave that steps from 2.5 volts to 0 volts at 0.5 nanoseconds. The actual voltage generated in response to the modeled voltage “undershoots” the modeled voltage at approximately 0.6 nanoseconds before settling to the desired voltage at approximately 1.0 nanoseconds. Undershoots may occur during a transition from a higher voltage value to a lower voltage value.

Voltage overshoots and undershoots occur in electrical components for a variety of reasons. In transistors, distributed and coupling capacitances and inductances of interconnects may readily contribute to voltage overshoots and undershoots. A transmission line mismatch in an input/output (I/O) device and a phenomenon commonly referred to as the “Miller effect” also may contribute to overshoots and undershoots in circuitry. The Miller effect is directed towards the simultaneous switching of both terminals of a capacitor, which modifies the effective capacitance between the terminals. The effective capacitance is capable of generating oscillatory noise that may cause overshoots and undershoots. When a transmission line is mismatched in an I/O device, energy may be directed back to the source, also creating oscillatory noise capable of generating overshoots and undershoots.

Although voltage overshoots and undershoots may not propagate via static complementary metal oxide semiconductor (CMOS) logic, overshoots and undershoots may contribute to noise and damage of electrical components. For example, overshoots and undershoots may lead to channel-hot-carrier (CHC) damage in n-channel metal oxide semiconductor (MOS) transistors. The channel-hot-carrier phenomenon occurs when the voltage overshoots and undershoots cause a significant increase in the magnitude of the horizontal and vertical electric fields in the channel region of MOS transistors. These elevated electric fields energize electrons and create holes in the channel, which are commonly referred to as “hot-carriers.” The hot carriers penetrate the gate oxide and cause a permanent shift in oxide charge distribution, ultimately degrading the current-voltage characteristics of the transistor.

Another degradation effect of voltage overshoots and undershoots on transistors is referred to as negative bias temperature instability (NBTI). Negative bias temperature instability occurs in p-channel MOS devices stressed with negative gate voltages at elevated temperatures. The phenomenon may result in permanent decreased drain current and an increased threshold voltage. Prolonged voltage overshoots and undershoots may lead to negative bias temperature instability in some circuitry.

Referring now to FIG. 3, an exemplary test methodology 300 is shown in accordance with embodiments of the invention. As can be appreciated, the ability to inject overshoots and undershoots into a circuit under test in accordance with embodiments of the invention may lead to the development of more accurate circuit reliability models. Such models may be used for channel-hot-carrier (CHC) degradation, negative bias temperature instability (NBTI), gate oxide reliability, and electro-migration. The test methodology 300 for generating such models may inject voltage overshoots and/or undershoots into the circuit under test for a period of time commonly referred to as the “stress interval.” Before the stress interval, a pre-stress characterization measurement may be taken of the device under test (block 302). The measurement may determine the frequency of oscillation and the quiescent state of current (IDDQ) through the power supply line (V_{DD}) of the device under test. During the stress interval, additional characterization measurements of the frequency of oscillation and the quiescent state of current through the power supply line may be obtained (block 306). The stress interval may end after a predetermined time period or a measurable condition, such as circuit failure, occurs (block 308). After the stress interval, a post-stress measurement may be obtained (block 310). Comparing the pre-stress characterization measurement, the characterization measurements obtained during the stress interval, and the post-test characterization measurement may reveal if and when the device under test begins to behave abnormally. The comparison may be accomplished, for example, by plotting the characterization measurements to produce graphs that reveal the behavior of the circuit under test before, after, and during the stress interval.

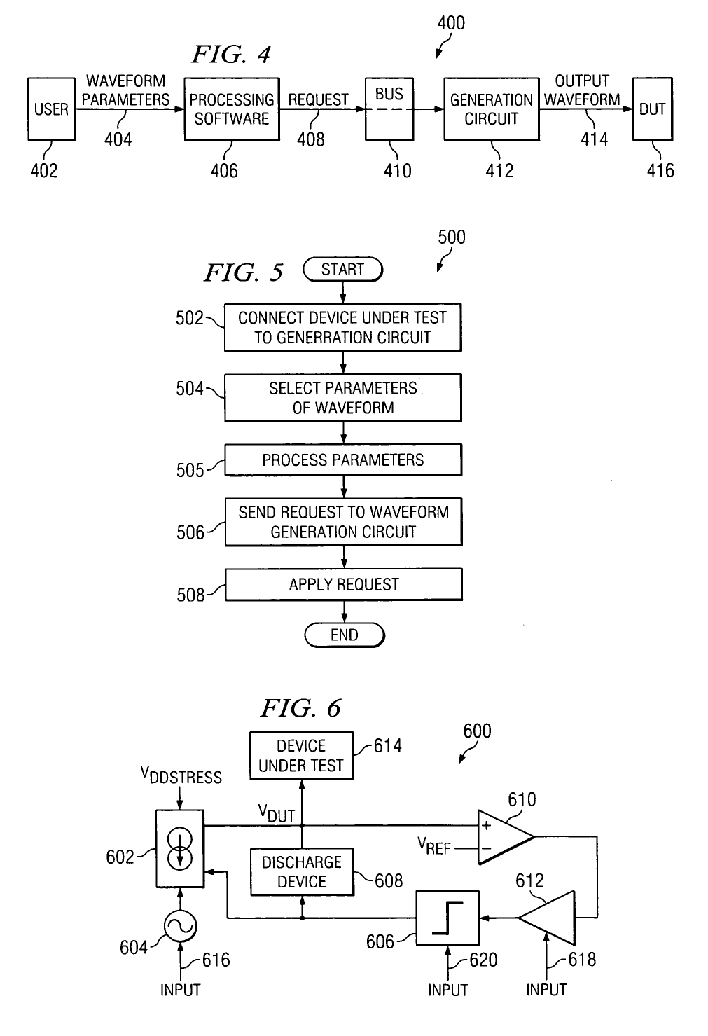

Referring now to FIG. 4, a block diagram of an exemplary waveform generation system 400 is shown in accordance with embodiments of the invention. As shown, a user 402 may select waveform parameters 404 describing a voltage waveform desired to be generated. The waveform parameters 404 preferably comprise the following five parameters: the type of waveform (e.g., an overshoot or undershoot), the magnitude of the waveform, the duration of the waveform, the frequency of the waveform, and the duty cycle of the waveform. Although typically all five parameters are selected by the user 402, certain combinations of parameters may also be selected by processing software 406. For example, an overshoot may be selected with defined magnitude, duration, and frequency parameters. The processing software 406 may determine an appropriate duty cycle for the overshoot or select an arbitrary duty cycle. The processing software 406 processes the waveform parameters 404 into a request 408 that is sent on a communications bus 410, such as an inter-IC (I²C) bus, to a waveform generation circuit 412. The generation circuit 412 utilizes the request 408 to generate an output waveform 414. The output waveform 412 may be applied to any desired electrical device under test 416 (DUT), such as a transistor or capacitor.

FIG. 5 depicts a procedure 500 for generating voltage waveforms in accordance with embodiments of the invention. The procedure 500 may start by connecting the device 414 to the waveform generation circuit (block 502). After the connection has been established, waveform parameters 404 may be selected (block 504). As previously discussed, the waveform parameters 404 may comprise the type of waveform (e.g., an overshoot or undershoot), the magnitude of the waveform, the duration of the waveform, the frequency of the waveform, and the duty cycle of the waveform. After selection of the waveform parameters 404, the processing software 406 may process the waveform parameters 404 into a request 408 (block 505). The request 408 may be sent on the bus 410 to the waveform generation circuit 412 (block 506). The request 408 may be applied to the waveform generation circuit 412 to generate a waveform corresponding to the parameters 404 (block 508).

Referring now to FIG. 6, a block diagram of an exemplary waveform generation circuit 600 that is capable of producing voltage overshoots in shown. As shown, the waveform generation circuit 600 comprises a current regulator 602, a controlled oscillator 604, a clock 606, a discharge device 608, a comparator 610, a programmable delay circuit 612, and a device under test 614. As can be appreciated by one of ordinary skill in the art, the functions related to each of the proceeding components may be implement with different components. The scope of the invention is intended to cover all such variations.

The current regulator 602 preferably comprises a voltage and temperature invariant charge pump that outputs current proportional to the frequency of the controlled oscillator 604. The clock 606 and the controlled oscillator 604 preferably operate in the gigahertz (10⁹ hertz) frequency range in order to produce voltage waveforms that overshoot the settled value for a duration on the order of picoseconds (10⁻¹² seconds). The clock 606 may comprise a phase locked loop (PLL) circuit, or any other type of controllable oscillator. The comparator 610 preferably possesses a fast switching to minimize the timing propagation into the programmable delay circuit 612. The programmable delay circuit 612 may comprise a chain of inverters, each inverter preferably representing approximately 20 picoseconds of delay. The frequency of the oscillator 604 may be controlled by an input 616, the period of delay caused by the programmable delay circuit 612 may be controlled by an input 618, and the frequency of the clock 606 may be controlled by an input 610.

Depending upon the voltage applied to the input 616, the oscillator 604 may produce a signal with a known frequency of oscillation. When a rising edge of the clock 606 enables the current regulator 602, the signal produced by the controlled oscillator 604 may cause the current regulator 602 to charge the V⁺ node of the comparator, thereby increasing the voltage of the device under test (V_{DUT}). When the V⁺ node of the comparator 610 becomes greater than the reference voltage V_{REF} applied to the V⁻ node, a delay is instantiated by the programmable delay circuit 612. During the delay, the current regulator 602 may continue to increase the voltage of the device under test (V_{DUT}) to a value of V_{DDSTRESS}. After the delay, a discharge mechanism is instantiated by the discharge device 608. During the discharge, the voltage of the device under test (V_{DUT}) is reduced to a nominal V_{DD} value. When a falling edge of the clock 606 disables the current regulator 602, the voltage of the device under test (V_{DUT}) is discharged to approximately zero volts. The process of charging and discharging the voltage of the device under test (V_{DUT}) may repeat ever cycle of the clock 606.

The input 616, the input 618, the input 620, the reference voltage V_{REF}, and the stress voltage V_{DDSTRESS} may be used to produce a desired overshoot voltage waveform at the V_{DUT} node that is in accordance with the waveform parameters 404 selected by a user. The current regulator 602 controls the magnitude of the overshoot via the V_{DDSTRESS} signal, the programmable delay circuit 612 controls the duration of the overshoot via the input 618, the clock 606 controls the frequency of waveform and the duty cycle of the waveform via the input 620.

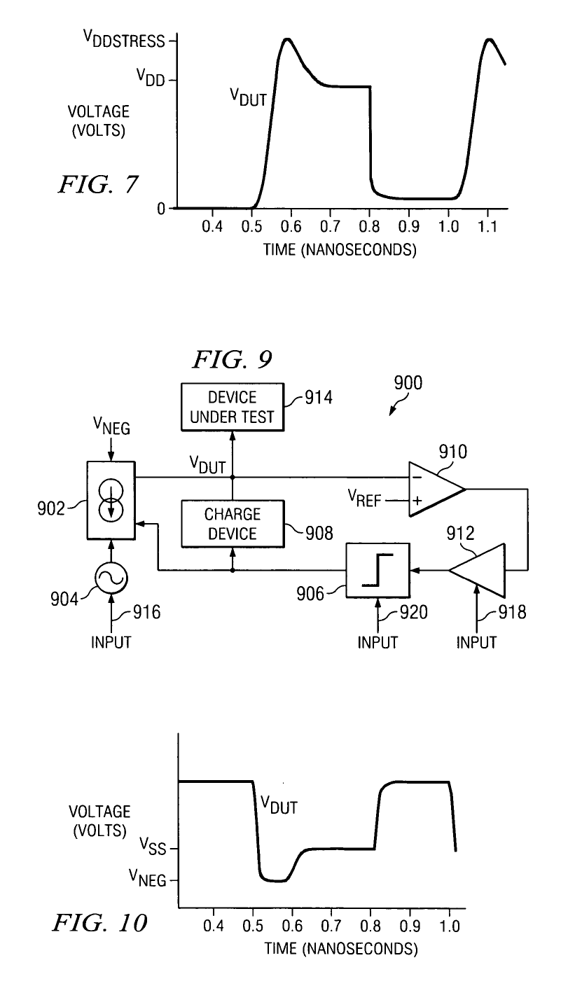

FIG. 7 illustrates an exemplary overshoot waveform generated by the waveform generation circuit 600. The generation process starts at approximately 0.5 nanoseconds with the current regulator 602 increasing the voltage at the V_{DUT} node to a value of V_{DDSTRESS} by 0.6 nanoseconds. The voltage remains at a value of V_{DDSTRESS} throughout the delay caused by the programmable delay circuit 612. After the delay, the voltage is discharged by the discharge device 608 to a nominal V_{DD} value. The current regulator 602 may pull down the voltage to roughly zero volts at approximately 0.8 nanoseconds. The waveform generation starts at the rising edge of the clock 606, which occurs appropriately at 0.5 nanoseconds, and completes after the falling edge of the clock 606, which occurs appropriately at 0.8 nanoseconds. The generation repeats ever clock cycle as desired.

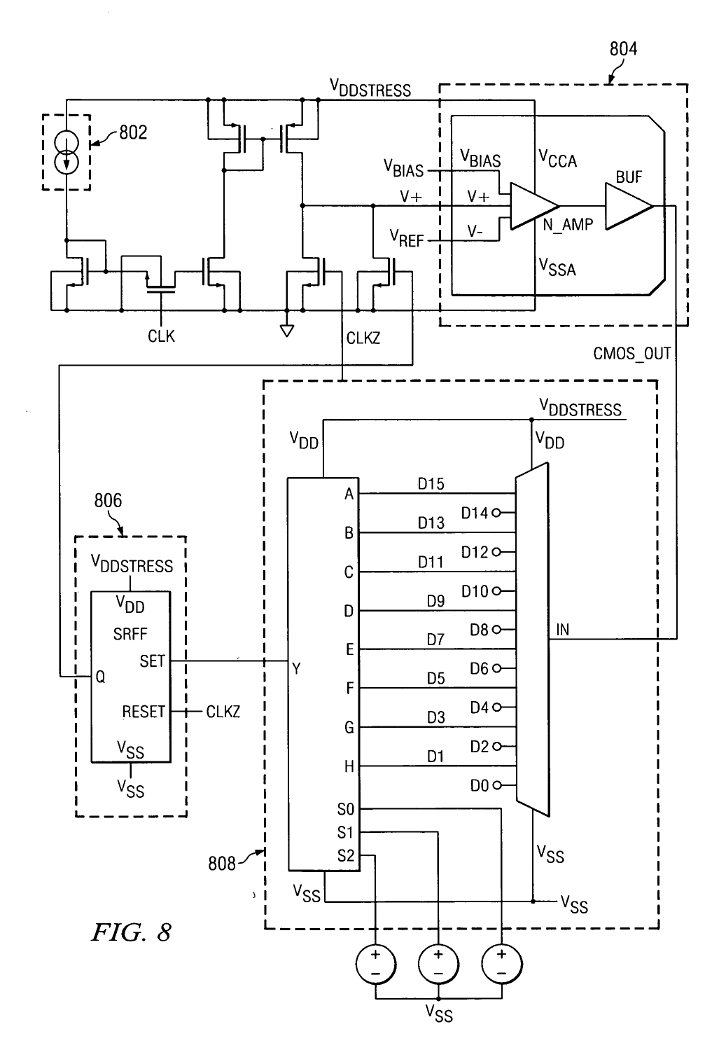

FIG. 8 illustrates an exemplary circuit-level implementation of the waveform generation circuit 600. The circuit is constructed using the components discussed in the foregoing discussion. More specifically, a current regulator 802 is coupled to a voltage comparator 804. The comparator 804 generates a rising edge once node V₊ is greater than V_{REF}. A set-reset (S/R) flip-flop 806 triggers the discharging transistor attached to node V₊ after an insertion delay introduced by a programmable delay circuit 808. Thus, the actual value of the overshoot voltage may be set by the value of V_{REF} and the duration of the overshoot may be set by the programmable delay circuit 808. As can be appreciated, equivalent circuits may be constructed using components with similar functionality. The scope of the invention is intended to cover all such variations.

Referring now to FIG. 9, a block diagram of an exemplary waveform generation circuit 900 that is capable of producing voltage undershoots in shown. As shown, the waveform generation circuit 900 comprises a current regulator 902, a controlled oscillator 904, a clock 906, a charging device 908, a comparator 910, a programmable delay circuit 912, and a device under test 914. As can be appreciated by one of ordinary skill in the art, the functions related to each of the proceeding components may be implement with different components. The scope of the invention is intended to cover all such variations.

The current regulator 902 preferably comprises a voltage and temperature invariant charge pump that outputs current proportional to the frequency of the controlled oscillator 904. The clock 906 and the controlled oscillator 904 preferably operate in the gigahertz frequency range in order to produce voltage waveforms that overshoot the settled value for a duration on the order of picoseconds. The clock 906 may comprise a phase locked loop (PLL) circuit, or any other type of controllable oscillator. The comparator 910 preferably possesses a fast switching to minimize the timing propagation into the programmable delay circuit 912. The programmable delay circuit 912 may comprise a chain of inverters, each inverter preferably representing approximately 100 picoseconds of delay. The frequency of the oscillator 904 may be controlled by an input 916, the period of delay caused by the programmable delay circuit 912 may be controlled by an input 918, and the frequency of the clock 906 may be controlled by an input 910.

Depending upon the voltage applied to the input 916, the oscillator 904 may produce a signal with a known frequency of oscillation. When a rising edge of the clock 906 enables the current regulator 902, the signal produced by the controlled oscillator 904 may cause the current regulator 902 to discharge the V⁻ node of the comparator, thereby decreasing the voltage of the device under test (V_{DUT}). When the V⁻ node of the comparator 910 becomes smaller than the reference voltage V_{REF} applied to the V⁺ node, a delay is instantiated by the programmable delay circuit 912. During the delay, the current regulator 902 may continue to decrease the voltage of the device under test (V_{DUT}) to a value of V_{NEG}. After the delay, a charging mechanism is instantiated by the charging device 908. During the charging mechanism, the voltage of the device under test (V_{DUT}) is increased to a nominal V_{SS} value. When a falling edge of the clock 906 disables the current regulator 902, the voltage of the device under test (V_{DUT}) is charged to the voltage value before waveform generation. The process of discharging and charging the voltage of the device under test (V_{DUT}) may repeat ever cycle of the clock 906.

The input 916, the input 918, the input 920, the reference voltage V_{REF}, and the stress voltage V_{NEG} may be used to produce a desired undershoot voltage waveform at the V_{DUT} node that is in accordance with the waveform parameters 404 selected by a user. The current regulator 902 controls the magnitude of the undershoot via the V_{NEG} signal, the programmable delay circuit 912 controls the duration of the overshoot via the input 918, the clock 906 controls the frequency of waveform and the duty cycle of the waveform via the input 920.

FIG. 10 illustrates an exemplary overshoot waveform generated by the waveform generation circuit 900. The generation process starts at approximately 0.5 nanoseconds with the current regulator 902 decreasing the voltage at the V_{DUT} node to a value of V_{NEG}. The voltage remains at a value of V_{NEG} throughout the delay caused by the programmable delay circuit 912. After the delay, the voltage is charged by the charging device 908 to a nominal V_{SS} value. The current regulator 902 may pull up the voltage at approximately 0.8 nanoseconds. The waveform generation starts at the rising edge of the clock 906, which occurs appropriately at 0.5 nanoseconds, and completes after the falling edge of the clock 906, which occurs appropriately at 0.8 nanoseconds. The generation repeats ever clock cycle as desired.

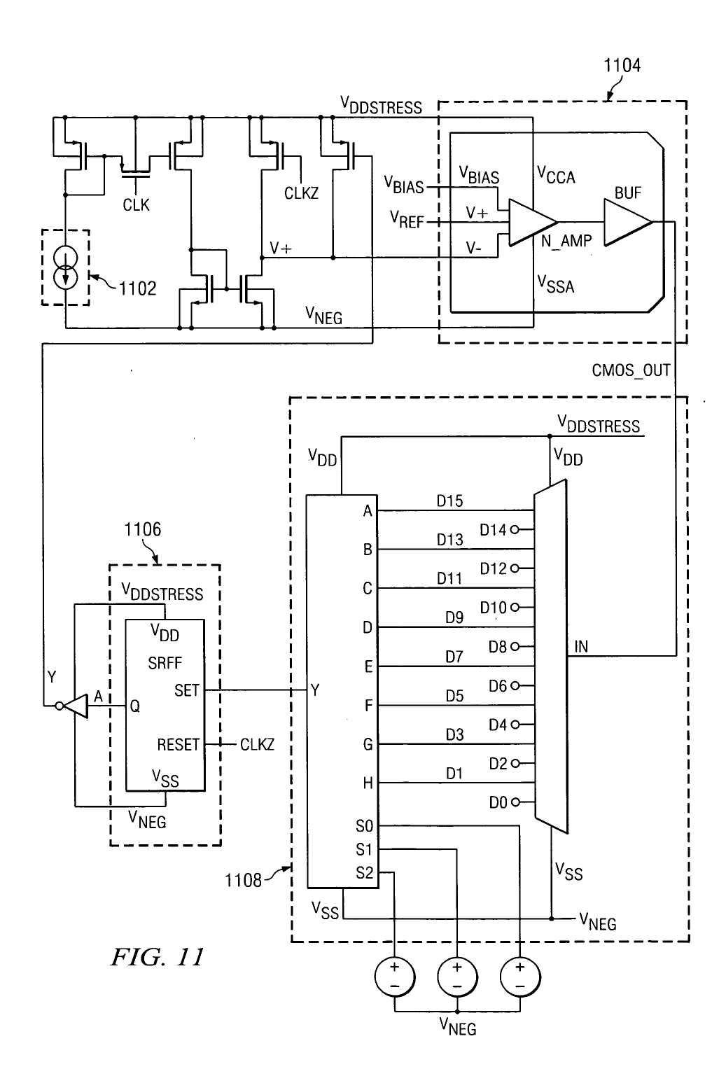

FIG. 11 illustrates an exemplary circuit-level implementation of the waveform generation circuit 900. The circuit is constructed using the components discussed in the foregoing discussion. More specifically, a current regulator 1102 is coupled to a voltage comparator 1104. The comparator 1104 generates a rising edge once the V node is smaller than V_{REF}. A set-reset (S/R) flip-flop 1106 triggers the charging transistor attached to V node after an insertion delay introduced by a programmable delay circuit 1108. Thus, the actual value of the overshoot voltage may be set by the value of V_{REF} and the duration of the overshoot may be set by the programmable delay circuit 1108. As can be appreciated, equivalent circuits may be constructed using components with similar functionality. The scope of the invention is intended to cover all such variations.

While the preferred embodiments of the present invention have been shown and described, modifications thereof can be made by one skilled in the art without departing from the spirit and teachings of the invention. The embodiments described herein are exemplary only, and are not intended to be limiting. Accordingly, the scope of protection is not limited by the description set out above.

1. A method, comprising:
processing a request for a voltage overshoot or undershoot to determine a plurality of inputs based, in part, on a plurality of waveform parameters;
applying the plurality of inputs to a waveform generation circuit; and
generating a voltage waveform in accordance with at least one of the parameters.

2. The method of claim 1 wherein the waveform generation circuit comprises an overshot waveform generation circuit, and the waveform parameters comprise voltage overshoot waveform parameters.

3. The method of claim 1 wherein the waveform generation circuit comprises an undershoot waveform generation circuit, and the waveform parameters comprise voltage undershoot waveform parameters.

4. The method of claim 1 wherein the waveform parameters are selected from the group consisting of a magnitude, a duration, a frequency, and a duty cycle.

5. The method of claim 1 wherein processing the request comprises determining an oscillation frequency.

6. The method of claim 1 wherein processing the request comprises determining a reference voltage for a comparator circuit.

7. The method of claim 1 wherein processing the request comprises determining a voltage value to apply to a delay circuit.

8. The method of claim 1 wherein processing the request comprises determining a voltage value to apply to a voltage controlled oscillator.

9. The method of claim 1 wherein processing the request further comprises processing the request based, in part, on the characteristics of the waveform generation circuit.

10. The method of claim 1 further comprising generating a circuit reliability model for a device coupled to the waveform generation circuit.

11. A circuit for generating voltage overshoots, comprising:
a current regulator adapted to generate voltage overshoot waveforms;
an oscillator coupled to the current regulator, the oscillator controls the operation of the current regulator; and
a programmable delay circuit adapted to control the duration of the overshoot in the voltage overshoot waveforms.

12. The circuit of claim 11 wherein the current regulator comprises a charge pump that is activated by a reference clock.

13. The circuit of claim 11 wherein the programmable delay circuit comprises a chain of inverting devices.

14. A circuit for generating voltage undershoots, comprising:
a current regulator adapted to generate voltage undershoot waveforms;
an oscillator coupled to the current regulator, the oscillator controls the operation of the current regulator; and
a programmable delay circuit adapted to control the duration of the overshoot in the voltage undershoot waveforms.

15. The circuit of claim 14 wherein the current regulator comprises a charge pump that is activated by a reference clock.

16. The circuit of claim 14 wherein the programmable delay circuit comprises a chain of inverting devices.

17. A method, comprising:
measuring a first frequency and magnitude of quiescent current through a supply line of a device under test;
injecting voltage overshoots or undershoots into a device under test; and
measuring, while injecting the voltage overshoots or undershoots, a second frequency and quiescent current through the supply line of the device under test.

18. The method of claim 17 wherein the first frequency comprises a pre-stress measurement.

19. The method of claim 17 wherein the first frequency comprises a post-stress measurement.

20. The method of claim 17 wherein the voltage overshoots or undershoots comprise voltage overshoots or undershoots of a predetermined magnitude.

21. The method of claim 17 wherein the voltage overshoots or undershoots comprises voltage overshoots or undershoots of a predetermined duration.
